(19) United States
(12) Patent Application Publication
(10) Pub. No.: US 2009/0301559 A1
(43) Pub. Date: Dec. 10, 2009

(54) SOLAR CELL HAVING A HIGH QUALITY REAR SURFACE SPIN-ON DIELECTRIC LAYER

(75) Inventors: Ajeet Rohatgi, Marietta, GA (US); Vichai Meemongkolkiat, Atlanta, GA (US); Saptharishi Ramanathan, Atlanta, GA (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Georgia Tech Research Corporation, Atlanta, GA (US)

(21) Appl. No.: 12/120,057

(22) Filed: May 13, 2008

(51) Int. Cl. H01L 31/02; H01L 31/028

(52) U.S. Cl. 136/256; 136/261

(57) ABSTRACT

A thin silicon solar cell having a high quality spin-on dielectric layer is described. Specifically, the solar cell may be fabricated from a crystalline silicon wafer having a thickness from 50 to 500 micrometers. A first dielectric layer is applied to the rear surface of the silicon wafer using a spin-on process. A high temperature furnace operation provides simultaneous emitter diffusion and front and rear surface passivation. During this high temperature operation, the front emitter is formed, the rear spin-on dielectric layer is cured, and the front dielectric layer is thermally grown. Barrier layers are formed on the dielectric layers. Openings are made in the barrier layers. Contacts are formed in the openings and on the back surface barrier layer.

### GOVERNMENT INTERESTS

The U.S. Government has a paid-up nonexclusive, nontransferable, worldwide license in this invention and the right in limited circumstances to require the patent owner to license others on reasonable terms as provided for by the terms of contract No. DE-FC36-07GO17023 awarded by the U.S. Department of Energy.

### FIELD OF THE INVENTION

The present invention generally relates to silicon solar cells. More particularly, the present invention relates to a spin-on process for simultaneous emitter diffusion and passivation on a back surface of the solar cell.

### BACKGROUND OF THE INVENTION

Solar cells are devices that convert light energy into electrical energy. These devices are also often called photovoltaic (PV) cells. Solar cells are manufactured from a wide variety of semiconductors. One common semiconductor material is crystalline silicon.

Solar cells have three main elements: (1) a semiconductor; (2) a semiconductor junction; and (3) conductive contacts. Semiconductors such as silicon may be doped n-type or p-type. If an n-type silicon and p-type silicon are formed in contact with one another, the region in the solar cell where they meet is a semiconductor junction. The semiconductor absorbs light. The energy from the light may be transferred to the valence electron of an atom in a silicon layer, which allows the valence electron to escape its bound state leaving behind a hole. These photogenerated electrons and holes are separated by the electric field associated with the p-n junction. The conductive contacts allow current to flow from the solar cell to an external circuit.

FIG. 1 shows the basic elements of a prior art solar cell. The solar cells can be fabricated on a silicon wafer. The solar cell 5 comprises a p-type silicon base 10, an n-type silicon emitter 20, bottom conductive contact 40, and a top conductive contact 50. The p-type silicon base 10 and the n-type silicon emitter 20 contact to form the junction. The n-type silicon 20 is coupled to the top conductive contact 50. The p-type silicon 10 is coupled to the bottom conductive contact 40. The top conductive contact 50 and the bottom conductive contact 40 are coupled to a load 75 to provide it with electricity.

The top conductive contact 50 (“front contact”), comprising silver, enables electric current to flow into the solar cell 5. The top conductive contact 50, however, does not cover the entire face of the cell 5 because silver is not entirely transparent to light. Thus, the top conductive contact 50 has a grid pattern to allow light to enter into the solar cell 5. Electrons flow from the top conductive contact 50, and through the load 75, before uniting with holes via the bottom conductive contact 40.

The bottom conductive contact 40 (“rear contact” or “back contact”) usually comprises aluminum-silicon eutectic. This conductive contact 40 typically covers the entire bottom of the p-type silicon 10 in order to maximize conduction. The aluminum is alloyed with silicon at high temperatures of approximately 750 degrees Celsius, well above the aluminum-silicon eutectic temperature of 577 degrees Celsius. This alloying reaction creates a heavily-doped p-type region at the bottom of the base and gives rise to a strong electric field there. This field aids in repelling the light-generated electrons from recombining with holes at the back contact so that they can be collected more efficiently at the p-n junction.

The interface between silicon and a conductive contact is typically an area having high recombination. For example, the back surface recombination velocity of an aluminum back surface field across the entire back surface may be 500 centimeters per second or more. High back surface recombination velocities decrease cell efficiency.

### SUMMARY OF THE INVENTION

Developing a cost effective solution to reduce rear surface recombination is important to the commercialization of high efficiency solar cells. One method that has been used to reduce recombination at the back contact is to form a dielectric layer of silicon dioxide on the rear surface of the silicon wafer. Local openings are then made to the dielectric layer to couple the back contact to the silicon wafer.

In the prior art, at least two high temperature furnace operations were used to form a diffused layer on the front surface, and silicon dioxide passivation on the front and rear surfaces. The first high temperature operation involved a diffusion process to form a diffused layer on the front surface. This was achieved by forming a masking layer on the rear surface prior to the diffusion process. After the first high temperature furnace operation, a chemical cleaner was applied to remove both the diffusion glass on the front surface and the masking layer on the rear surface. The second high temperature operation was then performed to oxidize the front and back surfaces for surface passivation.

The use of the back sacrificial masking layer and the use of two high temperature furnace operations increase the number of operations for fabricating a solar cell, and thus increase manufacturing costs. Moreover, a high quality rear surface passivation by silicon dioxide typically requires a growth of a thick silicon dioxide layer, which involves a high-temperature oxidation operation over a long period of time. This raises concerns of contaminants from the furnace contaminating the silicon wafer.

The solution as presented herein sets forth a spin-on based process for simultaneous emitter diffusion and front and rear surface passivation through a single high temperature furnace operation. The resulting solar cell device comprises a silicon wafer having a doped substrate. A spin-on dielectric layer may be coupled to the back surface of the doped substrate. A high temperature furnace step may be used to form a diffused layer on the front surface of the silicon wafer, and to form the front and back surface passivation layers. The front dielectric layer may be thermally grown during the same high temperature furnace operation. The back spin-on dielectric layer may be cured during the same high temperature furnace operation. Barrier layers may be formed on the dielectric layers. Openings may be made into the barrier layers and the dielectric layers. Contacts may be formed on the front and back surfaces, including into the openings.

The foregoing is a summary and thus contains, by necessity, simplifications, generalizations and omissions of detail; consequently, those skilled in the art will appreciate that the summary is illustrative only and is not intended to be in any way limiting. Other aspects, inventive features, and advantages of the present disclosure, as defined solely by the claims, will become apparent in the non-limiting detailed description set forth below.

### BRIEF DESCRIPTION OF THE DRAWINGS

FIG. 1 is a cross-sectional view of a prior art solar cell.

FIG. 2 is a flowchart for one embodiment of a process for simultaneous emitter diffusion and rear surface passivation.

FIG. 3 is a stacking diagram showing the load positions of source and target wafers.

FIGS. 4A to 4F are cross-sectional views for one embodiment of a silicon wafer at various stages of the fabrication process.

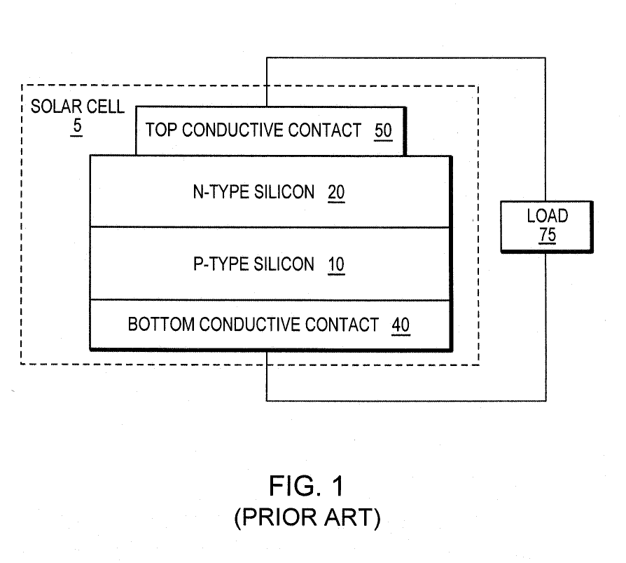

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components, and circuits have not been described in detail so as not to obscure the present invention.

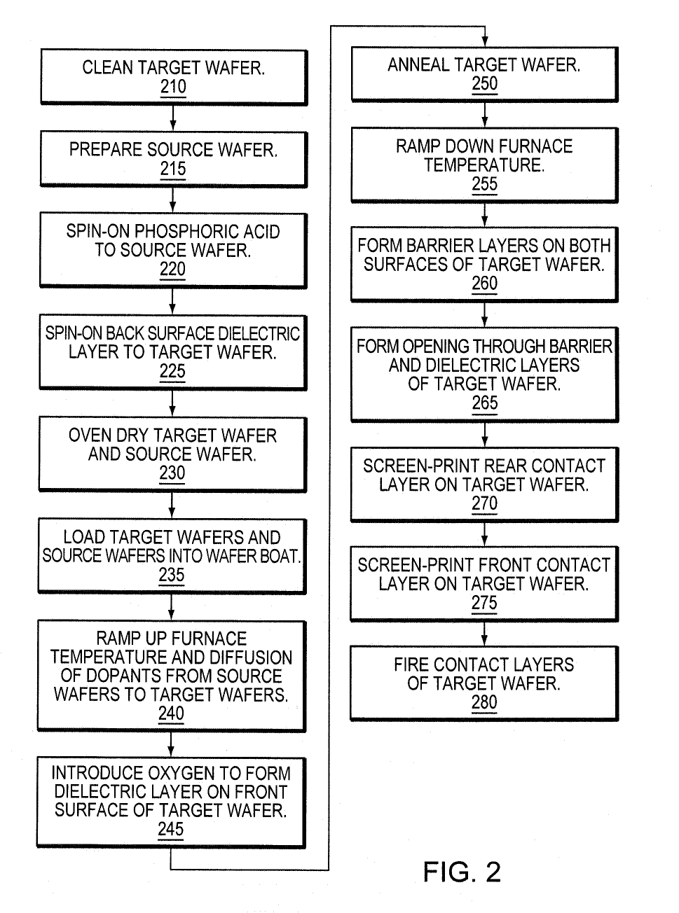

FIG. 2 is a flowchart for one embodiment of a process for creating simultaneous emitter diffusion and front and rear surface passivation. To minimize handling of cell wafers, this process involves a single diffusion and oxidation furnace operation. The process starts with silicon wafers, one of which is used as a dopant source wafer and the other of which is a target wafer on which the solar cell is to be formed. The target wafers may be Czochralski or Float Zone wafers. The target wafers may have a thickness from 50 to 500 micrometers. The target wafers may have a p-type substrate. Alternatively, the target wafers may be p-type.

In operation 210, target silicon wafers are cleaned. The target wafers may be cleaned by dipping the wafers into a hydrofluoric acid solution to remove oxides from the surfaces. For example, the hydrofluoric acid solution can be 20:1 H₂O:HF by volume. The diluted hydrofluoric acid solution is applied to the surface of the wafer. The native oxide layer is thereby removed from the silicon wafer. Initially, the solution will adhere to the silicon wafer as it attacks the oxide layer. Upon removal of the oxide layer from the silicon, the solution becomes phobic to the surface and will thus strain off.

In operation 215, source wafers are prepared. The source wafers may be used as a dopant source to create diffused layers on the target wafers. This preparation may involve dipping the source wafers into a bath of sulfuric acid solution (2:1:1 H₂0:H₂O₂:H₂SO₄) by volume for a time period from two to 20 minutes. The sulfuric acid solution creates uniform hydrophilic surfaces on the source wafers.

In operation 220, a phosphoric acid solution is applied to a surface of the source wafer. To create the phosphoric acid solution, phosphoric acid (H₃PO₄) may be mixed with ethanol (C₂H₅OH). The resulting mixture may be from 0.25 to four percent phosphorous pentoxide (P₂O₅) by weight. The phosphoric acid solution is then spun-on to the source wafers. Each source wafer may be loaded to the center of a spin-on chuck. The solution may be dripped over the source wafer using a pipette and the source wafer may be spun. For one embodiment of the invention, the spin-on equipment may be set from 2000 to 3000 rotations per minute for a time period from 15 to 45 seconds. For another embodiment of the invention, the spin-on equipment may be set to 2500 rotations per minute for 30 seconds.

In operation 225, a dielectric layer is applied to the back surface of the target wafer. For one embodiment of the invention, a pipette may be used to drip a silicon dioxide solution around the center of the target wafer and the target wafer may be spun. The silicon dioxide solution may be a silicon dioxide sol-gel that is commercially available from Filmtronics, Inc. under the name “20B.” The spin-on dielectric layer may have high purity and may be annealed in a furnace without contaminating the target wafer. The thickness of the dielectric layer formed on the target wafer may be from 1000 to 3000 angstroms. For one embodiment of the invention, the spin-on equipment may be set from 3000 to 5000 rotations per minute for a time period from 10 to 30 seconds. For another embodiment of the invention, the spin-on equipment may be set to 4000 rotations per minute for 15 seconds.

In operation 230, the target wafers and the source wafers are put in a carrier and dried in an oven or furnace having a temperature from 100 to 300 degrees Celsius. The wafers may be dried for a time period from five to 30 minutes.

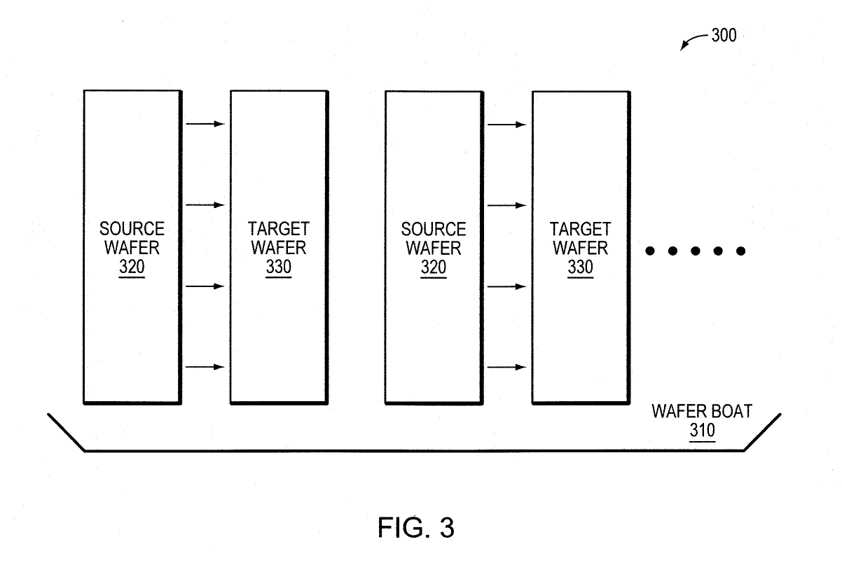

In operation 235, the target wafers and source wafers are loaded to a wafer boat to prepare for the diffusion process. The diffusion furnace 300 may be heated to a temperature from 600 to 800 degrees Celsius before the wafer boat 310 is loaded. The wafer boat may be inside or outside the furnace during the loading process. FIG. 3 depicts one embodiment of a stacking diagram that shows loading positions of source wafers 320 and target wafers 330 on the wafer boat 310. The wafers may be positioned such that the phosphoric acid side of a source wafer 320 is facing the front surface of a corresponding target wafer 330. The placement pattern for each source wafer 320 and target wafer 330 pair may be repeated until the wafer boat 310 is completely loaded. Each wafer may be spaced from 1/16 to ⅛ inch center-to-center from an adjacent wafer. If the wafer boat 310 is loaded with wafers outside of the diffusion furnace 300, the wafer boat 310 may be placed into the diffusion furnace 300 after the wafer boat 310 is fully loaded. Once the diffusion furnace contains a full wafer boat 310, nitrogen (N₂) may be injected into the furnace at a rate from one to five liters per minute for seven to 15 minutes.

In operation 240, the temperature inside the furnace is ramped up to a peak temperature from 850 to 950 degrees Celsius. The ramp up time may be from five to 40 minutes. Once the peak temperature is reached, the process is maintained in steady state for between seven and 45 minutes. The nitrogen flow assists in entraining the dopants from source wafers to target wafers. Because nitrogen is inert, it has no reactive impact on the target wafers. The phosphorous precursor from the source wafers is transferred to the front surfaces of the target wafers. The phosphorous may then diffuse into the front sides of the target wafers. The general transfer pattern of a phosphorous precursor from source wafer to target wafer is shown by the arrows in FIG. 3. The furnace may be from five to seven inches in diameter and from 40 to 50 inches in length. A diffusion layer with a thickness from 0.3 to 0.8 micrometers may be formed on the target wafer.

The heat treatment simultaneously cures and strengthens the bond between the silicon and dielectric interface, and improves passivation. The surface recombination velocity after curing may be from 200 to 300 centimeters per second on a 2.5 ohm-centimeter p-type silicon substrate. The dielectric layer on the back surface of a target wafer may also protect the target wafer from phosphorous diffusion on the back surface. Simultaneously providing emitter diffusion and rear surface passivation in a single operation reduces the number of steps for fabricating a solar cell, and thus reduces manufacturing costs.

In operation 245, a dielectric layer may be grown on the front surface of the target wafer. The nitrogen flow may be terminated and oxygen may be added to the reaction mixture at a flow rate from one to three liters per minute. The oxidation may be for a time period from three to 10 minutes. The dielectric layer formed on the front surface may have a thickness from 100 to 200 angstroms. During this operation, the back surface dielectric layer thickness may increase if oxygen penetrates the spin-on dielectric layer to form silicon dioxide at the silicon interface. An increase in the thickness of the spin-on dielectric layer in operation 245 may improve passivation properties.

In operation 250, the dielectric layers may be annealed in nitrogen for ten to 15 minutes at the peak temperature. Annealing the dielectric layers may help to stabilize the dielectric layer.

In operation 255, the process temperature is reduced to approximately 700 degrees Celsius for a time period from 30 to 60 minutes. This temperature reduction may be achieved by turning off the heating element in the furnace. Once the temperature is reduced to approximately 700 degrees Celsius, the wafers may be removed from the wafer boat. The removed wafers may be quality tested. For example, sheet resistances and implied voltages of the removed wafers may be analyzed.

In operation 260, silicon nitride may be formed on both sides of the wafer using a plasma enhanced chemical vapor deposition (PECVD) process with a suitable reaction chamber. The silicon nitride layers act as barrier layers that protect the dielectric layers. Moreover, the silicon nitride layers in combination with the dielectric layers improve passivation. The surface recombination velocity of the dielectric layer after silicon nitride is deposited is from 20 to 25 centimeter per second on a 2.5 ohm-centimeter p-type silicon substrate. The barrier layer on the front surface also provides an anti-reflective coating to help absorb light. The barrier layers may have thicknesses from 100 to 700 angstroms.

In operation 265, openings are formed in the barrier layers of the front surface and the back surface. Alternatively, openings are formed only in the barrier layer of the back surface. The openings may be formed using a solar etch paste. One example of the etch paste is manufactured by Merck & Co., Inc. under the name “Solar Etch AX M1. The etch paste may be screen printed on the front and back surfaces of the solar cell. A temperature from 300 to 400 degrees Celsius may then be applied to the etch paste to etch through the nitride layer. Following the etch, the wafer may be dipped in a buffered oxide etchant (BOE) to remove any remaining silicon nitride residue, as well as to remove the dielectric layer to expose the silicon wafer. The BOE may comprise ammonium fluoride (NH₃F). For another embodiment of the invention, hydrofluoric acid (HF) solution may be used instead of the BOE. For yet another embodiment of the invention, a laser may be used to create the openings to the silicon wafer.

In operation 270, a fritless aluminum paste is screen printed on the rear surface of the silicon wafer, including in openings formed on the rear surface in operation 265. The aluminum paste may comprise an aluminum and silicon alloy having one to 12 atomic percent silicon. The aluminum paste may be product number: AL 53-090, AL 53-110, AL 53-120, AL 53-130, AL 53-131, or AL 5540 which are all commercially available from Ferro Corporation. At the opening, the alloy may form a back surface field having a thickness from six to 15 micrometers.

In operation 275, a silver paste is screen printed on the front surface. The silver paste may be manufactured by Heraeus Holding HmbH under product numbers 8969 or 8998. This silver paste may penetrate the barrier layer and the dielectric layer if no opening was formed in the front surface in operation 265.

In operation 280, the front and rear surface contacts are co-fired in a furnace. The furnace may be heated to a peak temperature from 700 to 900 degrees Celsius. The ramp up time may be from 10 seconds to three minutes. The peak temperature may be held for one to five seconds. The ramp down time may be less than two minutes.

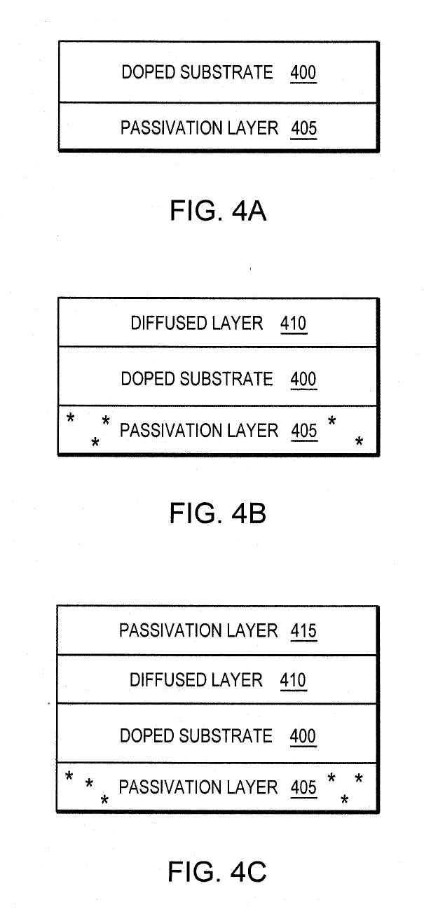

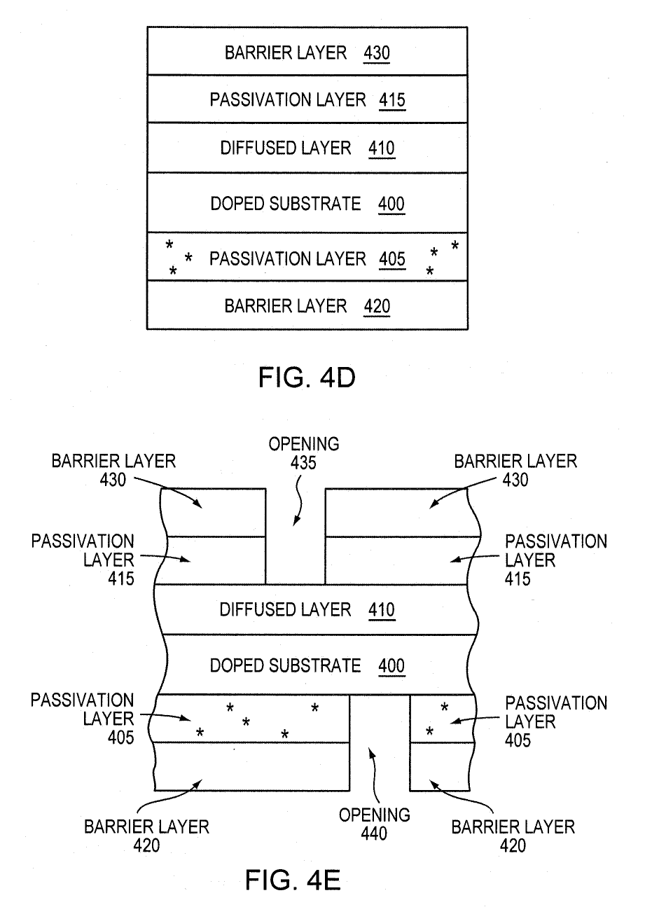

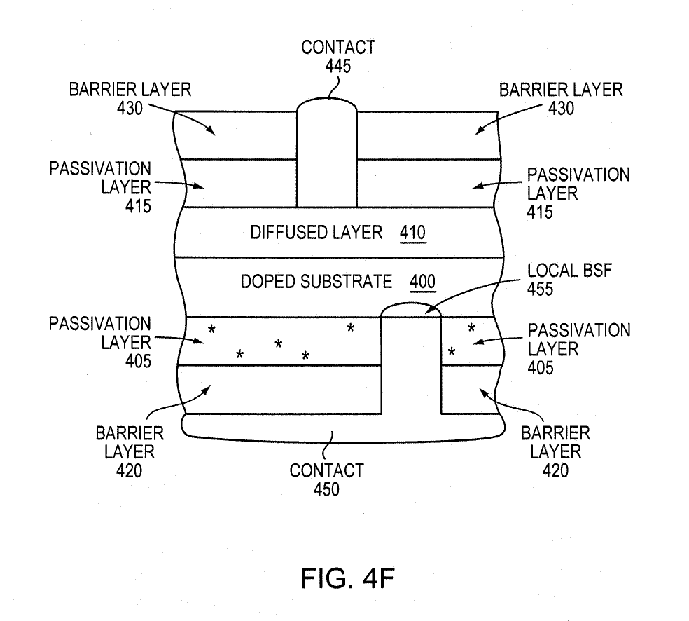

FIG. 4A through 4F depict cross-sectional views for one embodiment of a silicon wafer at various stages in the fabrication process. FIG. 4A depicts a silicon wafer having a doped substrate 400 coupled to a passivation layer 405. The substrate 400 may be doped p-type. The passivation layer 405 may comprise a dielectric such as silicon dioxide. The passivation layer 405 may be applied by a spin-on process as described above. The passivation layer 405 may comprise silicon dioxide. The passivation layer 405 may have a thickness from 1500 to 2500 angstroms.

A diffused layer 410 is formed in the doped substrate 400 in FIG. 4B. The diffused layer 410 may be n-type. During the diffusion process, the spin-on dielectric layer is simultaneously cured to strengthen bonds, creating a high quality dielectric. This high quality dielectric is reflected by the asterisks in the passivation layer 405 of FIG. 4B.

FIG. 4C depicts a passivation layer 415 that contacts the diffused layer 410. The passivation layer 415 may be comprised of a thermally grown dielectric such as silicon dioxide. The passivation layer 415 may have a thickness from 100 to 200 angstroms.

FIG. 4D depicts a first barrier layer 420 that contacts the passivation layer 405 and a second barrier layer 430 that contacts the passivation layer 415. The barrier layers 420, 430 may be comprised of silicon nitride that is formed by PECVD. The barrier layers 420, 430 provide protection to the passivation layers 405, 415. The barrier layers may comprise a hydrogen concentration from 4×10²¹ to 7×10²² atoms per cubic centimeter. Hydrogen may be incorporated into the silicon nitride layer by the PECVD precursors. During the PECVD process, hydrogen may also be incorporated into the silicon and passivation layer interfaces to help improve the surface passivation quality. During the heat treatment, hydrogen may be disassociated from the barrier layer. The hydrogen atoms may then further help passivation of both the surfaces and the bulk region of the silicon wafer by attaching to defects. Moreover, barrier layer 430 may provide an anti-reflective coating to the front surface of the solar cell.

The passivation layer 405 may help to prevent inversion. If nitride is in direct contact with silicon, the positive charges of the nitride layer may attract electrons to the surface which may cause shunting. The passivation layer 405 separates the barrier layer 420 from the doped substrate 400 to avoid disadvantageous shunting of the solar cell.

FIG. 4E depicts an opening 440 in the passivation layer 405 and the barrier layer 420. An opening 435 may also be formed in the passivation layer 415 and the barrier layer 430. For one embodiment of the invention, the opening 440 may be formed by applying a solar etch paste to the barrier layer 420 and then applying a heat treatment to the barrier layer. The heat treatment may involve a temperature from 300 to 380 degrees Celsius. The heat treatment may dissolve the barrier layer under the paste, forming an opening to the passivation layer 405. Dipping the wafer in BOE may remove any remaining silicon nitride residue as well as a portion of the passivation layer 405.

Similarly, the opening 435 may be formed by applying a solar etch paste to the barrier layer 430 and applying a heat treatment to the barrier layer. The heat treatment may dissolve the barrier layer under the paste, forming an opening to the passivation layer 415. Dipping the wafer in BOE may remove any remaining silicon nitride residue as well as a portion of passivation layer 415.

For another embodiment of the invention, the opening 435 and opening 440 may be formed by a laser. For yet another embodiment of the invention, the opening 435 and opening 440 may be formed by a mechanical scribe.

FIG. 4F depicts a rear contact 450 that is coupled to the passivation layer 405, the barrier layer 420, and the doped substrate 400 via the opening 440. This rear contact may be comprised of aluminum. Alternatively, this rear contact may be comprised of aluminum having from one to 12 atomic percent silicon. The addition of the silicon in the aluminum provides for a high quality BSF 455 having a depth from six to 15 micrometers.

FIG. 4F depicts a front contact 445 that is coupled to the barrier layer 430, the passivation layer 415, and the diffused layer 410. The contact 445 may comprise silver.

In the solar cell devices and processes described herein, it will be appreciated that the use of the spin-on dielectric on the back surface prevents auto-diffusion of n-type dopant into the back surface. Thus, the n-type dopant does not form another p-n junction on the back surface, which can degrade performance of the resulting solar cell by a shunting mechanism.

Moreover, the presence of the relatively thick spin-on dielectric on the back surface avoids placing silicon nitride in direct contact or near proximity to the p-type silicon substrate. Silicon nitride is rich in positive charge, and its presence in contact with or near the p-type silicon substrate can cause inversion of charge carriers at the solar cell's back surface. The relatively thick spin-on dielectric layer thus avoids inversion problems.

Finally, the solar cell device and processes described herein achieve enhanced passivation by converting the spin-on dielectric layer from a low to high quality dielectric layer through a high temperature heat treatment used to diffuse dopant into the solar cell device and to perform oxidation to form the relatively thin oxide layer on the front surface of the solar cell. Enhanced passivation reduces or eliminates the recombination centers resulting from dangling bonds on the surfaces, and thus leads to better performance of the resulting solar cell.

In the forgoing specification, the invention has been described with reference to specific exemplary embodiments thereof. It will, however, be evident that various modification and changes may be made thereto without departure from the broader spirit and scope of the invention as set forth in the appended claims. The specification and drawings are, accordingly, to be regarded in an illustrative rather than restrictive sense.

What is claimed is:

1. A solar cell, comprising:
a thin crystalline silicon wafer having a thickness less than 300 micrometers comprising a p-region coupled to an n-region;
a spin-on dielectric layer coupled to the rear surface of the silicon wafer to protect the silicon wafer from contaminants during a diffusion process and to provide rear surface passivation, wherein the spin-on dielectric layer has a thickness from 1500 to 2500 angstroms, wherein the spin-on dielectric layer has strengthened bonds through a curing process performed during the diffusion process;
a thermally grown dielectric layer coupled to the front surface of the silicon wafer to provide front surface passivation, wherein the thermally grown dielectric layer has a thickness from 100 to 200 angstroms.

2. The solar cell of claim 1, further comprising:
a first barrier layer coupled to the spin-on dielectric layer to protect the spin-on dielectric layer, wherein the first barrier layer and the spin-on dielectric layer define an opening to the silicon wafer.

3. The solar cell of claim 2, further comprising:
a back contact coupled to the silicon wafer, the spin-on dielectric layer, and the first barrier layer to conduct electric charge.

4. The solar cell of claim 3, wherein the back contact comprises an aluminum and silicon alloy, wherein the alloy forms a back surface field having a thickness from six to 15 micrometers at the opening.

5. The solar cell of claim 4, wherein the alloy comprises from one to 12 atomic percent silicon.

6. The solar cell of claim 2, further comprising:
a second barrier layer coupled to the thermally grown dielectric layer to protect the dielectric layer, wherein the second barrier layer and the thermally grown dielectric layer define an opening to the silicon wafer.

7. The solar cell of claim 6, further comprising:
a front contact coupled to the silicon wafer through the thermally grown dielectric layer and the second barrier layer to conduct electric charge.

8. The solar cell of claim 2, wherein the first barrier layer comprises silicon nitride.

9. The solar cell of claim 8, wherein the spin-on dielectric layer comprises silicon dioxide.

10. The solar cell of claim 9, wherein the spin-on dielectric layer in combination with the first barrier layer has a recombination velocity from 20 to 25 centimeter per second.
